(19) United States
(12) Patent Application Publication
(10) Pub. No.: US 2013/0075905 A1
(43) Pub. Date: Mar. 28, 2013

(54) Semiconductor Chips and Semiconductor Packages and Methods of Fabricating the Same

(71) Applicants: Ju-il Choi, Suwon-si (KR); Jeong-Woo Park, Suwon-si (KR); Jeonggi Jin, Osan-si (KR); Hyungseok Kim, Seoul (KR)

(72) Inventors: Ju-il Choi, Suwon-si (KR); Jeong-Woo Park, Suwon-si (KR); Jeonggi Jin, Osan-si (KR); Hyungseok Kim, Seoul (KR)

(73) Assignee: Samsung Electronics Co., Ltd.

(21) Appl. No.: 13/602,581

(22) Filed: Sep. 4, 2012

(30) Foreign Application Priority Data
Sep. 23, 2011 (KR) 10-2011-0096486

(51) Int. Cl. H01L 23/48; H01L 23/532

(52) U.S. Cl. 257/738; 257/751; 257/E23.023; 257/E23.16

(57) ABSTRACT

A semiconductor device includes a substrate and a through via penetrating the substrate. The through via has a protruding portion at a first end thereof extending out from a first surface of the substrate and a second end of the via contacting an interconnection line proximate a second, opposite, end of the substrate. A wetting layer is positioned between the via and the substrate and extends over the protruding portion of the via. The wetting layer includes a material selected to improve an adhesive strength between the wetting layer and a solder ball contacting the wetting layer extending over the protruding portion of the via when a solder ball is coupled to the wetting layer.

### CROSS-REFERENCE TO RELATED APPLICATIONS

This U.S. non-provisional patent application claims priority under 35 U.S.C. §119 to Korean Patent Application No. 10-2011-0096486, filed on Sep. 23, 2011, in the Korean Intellectual Property Office, the entire contents of which are hereby incorporated by reference.

### BACKGROUND OF THE INVENTION

Embodiments of the inventive concepts relate to semiconductor chips, semiconductor packages including the same, and methods of fabricating the same.

Packaging technology is continuously being developed to meet requirements for small-sized and highly reliable semiconductor products. Such technologies include stacking techniques, in which two or more chips or two or more packages are stacked along a vertical direction, which have been intensively developed to meet the requirement for small-sized and high performance electronic products.

Due to the use of the stacking techniques, it may be possible to realize, for example, a memory device with an increased capacity, which may be two or more times higher than a chip-level capacity realized by a process of integrating each semiconductor chip. In addition to the increase in capacity, various technical advantages, such as high efficiency in packaging density and/or packaging area, may be achieved from semiconductor packages fabricated by the stacking technique.

In the meantime, there is an increasing demand for a flip-chip bonding technique, because it can improve a signal transmitting speed of the stack-type semiconductor package. In a stack structure fabricated by the flip-chip bonding technique, a through-silicon via may be used to transmit signals between chips or packages thereof.

### SUMMARY

Some embodiments provide a semiconductor device including a substrate and a through via penetrating the substrate. The through via has a protruding portion at a first end thereof extending out from a first surface of the substrate and a second end of the via contacting an interconnection line proximate a second, opposite, end of the substrate. A wetting layer is positioned between the via and the substrate and extends over the protruding portion of the via. The wetting layer includes a material selected to improve an adhesive strength between the wetting layer and a solder ball contacting the wetting layer extending over the protruding portion of the via when a solder ball is coupled to the wetting layer.

In other embodiments, the wetting layer includes at least one of gold (Au), palladium (Pd) and platinum (Pt) and the device further includes a first and second barrier layer. The first barrier layer is interposed between the wetting layer and the substrate. The first barrier layer does not extend over at least a portion of the protruding portion. The second barrier layer is interposed between the wetting layer and the via. The first and second material layers comprise a material selected to limit diffusion of gold (Au), palladium (Pd) and platinum (Pt) from the wetting layer.

In further embodiments, the first barrier layer extends over only a lower portion of sidewalls of the protruding portion and does not extend over an upper portion of the sidewalls or an upper surface of the protruding portion so that the solder ball contacting the wetting layer on the upper surface and the upper portion of the sidewalls of the protruding portion.

In other embodiments, the semiconductor device includes a seed layer positioned between the via and the second barrier layer. At least one of the seed layer and the via include copper. The second barrier layer comprises a material selected to limit diffusion of copper from the at least one of the seed layer and the via. The first barrier layer and the second barrier layer may include at least one of titanium, titanium nitride, tantalum, and tantalum nitride. The device may further include a contact barrier layer positioned between the at least one of the seed layer and the via and the interconnection line. The contact barrier layer may be a material selected to limit diffusion of copper from the at least one of the seed layer and the via to the interconnection line.

In further embodiments, a semiconductor package includes the semiconductor device as described above as a first semiconductor device. The semiconductor package further includes a second semiconductor device stacked on the first semiconductor device and having a conductive component positioned proximate the protruding portion of the via. The solder ball is positioned between the wetting layer and the conductive component of the second semiconductor device and forms an electrical connection between the via and the conductive component including an intermetallic component (IMC) layer formed by interfusion between the wetting layer and the solder ball. The IMC layer may extend to cover at least a portion of a sidewall of the protruding portion of the via having the wetting layer thereon.

In other embodiments, the second semiconductor device includes a through via penetrating a substrate thereof and having a protruding portion. The protruding portion of the through via of the second semiconductor device is positioned proximate the protruding portion of the via of the first semiconductor device with the solder ball and IMC therebetween.

In further embodiments, the second semiconductor device includes a through via penetrating a substrate thereof and having a protruding portion at a first end thereof and an interconnection line proximate a second, opposite end thereof. The solder ball is positioned between the protruding portion of the first semiconductor device and the interconnection line of the second semiconductor device.

In yet further embodiments, a method of forming a semiconductor device includes forming a hole in a substrate of the semiconductor device and sequentially conformally forming a first barrier layer, a wetting layer and a second barrier layer in the hole using a deposition process. A through via is formed on the second barrier layer to fill the hole. A surface of the substrate is etched back to define a protruding portion of the via extending out from the surface of the substrate. Etching back the surface includes removing the first barrier layer from an upper surface and a portion of sidewalls of the protruding portion without removing the wetting layer. The wetting layer includes a material selected to improve an adhesive strength between the wetting layer and a solder ball contacting the wetting layer extending over the protruding portion of the via when a solder ball is coupled to the wetting layer.

In other embodiments, forming a hole is preceded by forming an interlayer dielectric layer including an integrated circuit therein on an opposite, second surface of the substrate. Forming the hole includes forming the hole through the interlayer dielectric layer. Sequentially conformally forming includes forming the first barrier layer, the wetting layer and the second barrier layer on an upper surface of the interlayer dielectric layer. Forming the through via includes forming the through via filling the hole an extending over the upper surface of the interlayer dielectric layer. Forming the through via is followed by planarizing the upper surface of the interlayer dielectric layer to expose the upper surface of the interlayer dielectric layer. Interconnection lines are formed on the upper surface of the interlayer dielectric layer that electrically couple the via in the hole to the integrated circuit in the interlayer dielectric layer. A conductive bump including a solder ball is formed on the upper surface of the interlayer dielectric layer aligned with the via and electrically connected to the interconnection lines and the via.

### BRIEF DESCRIPTION OF THE DRAWINGS

Example embodiments will be more clearly understood from the following brief description taken in conjunction with the accompanying drawings. FIGS. 1 through 16 represent non-limiting, example embodiments as described herein.

FIG. 1 is a cross sectional view of a semiconductor chip according to example embodiments of the inventive concepts;

FIG. 2 is an enlarged cross sectional view of a portion A of FIG. 1;

FIGS. 3 through 9 are cross sectional views illustrating methods of fabricating the semiconductor chip of FIG. 2 according to some embodiments;

FIGS. 10 and 11 are cross sectional views illustrating methods of fabricating a semiconductor package according to example embodiments of the inventive concepts;

FIG. 12 is an enlarged cross sectional view of a portion B of FIG. 11;

FIG. 13 is an enlarged cross sectional view of a semiconductor chip according to other example embodiments of the inventive concepts;

FIG. 14 is a cross sectional view of a semiconductor package according to other example embodiments of the inventive concepts;

FIG. 15 is a schematic block diagram of a memory card including a semiconductor device according to example embodiments of the inventive concepts; and

FIG. 16 is a schematic block diagram of an information processing system including a semiconductor device according to example embodiments of the inventive concepts.

### DETAILED DESCRIPTION

Advantages and features of the present inventive concept and methods of accomplishing the same may be understood more readily by reference to the following detailed description of preferred embodiments and the accompanying drawings. The present inventive concept may, however, be embodied in many different forms and should not be construed as being limited to the embodiments set forth herein. Rather, these embodiments are provided so that this disclosure will be thorough and complete and will fully convey the concept of the invention to those skilled in the art, and the present inventive concept will only be defined by the appended claims. Like reference numerals refer to like elements throughout the specification.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on”, “directly connected to” or “directly coupled to” another element or layer, there are no intervening elements or layers present. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath”, “below”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Embodiments are described herein with reference to cross section illustrations that are schematic illustrations of idealized embodiments (and intermediate structures). As such, variations from the shapes of the illustrations as a result, for example, of manufacturing techniques and/or tolerances, are to be expected. Thus, these embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which the present inventive concept belongs. It will be further understood that terms, such as those defined in commonly used dictionaries, should be interpreted as having a meaning that is consistent with their meaning in the context of the relevant art and this specification and will not be interpreted in an idealized or overly formal sense unless expressly so defined herein.

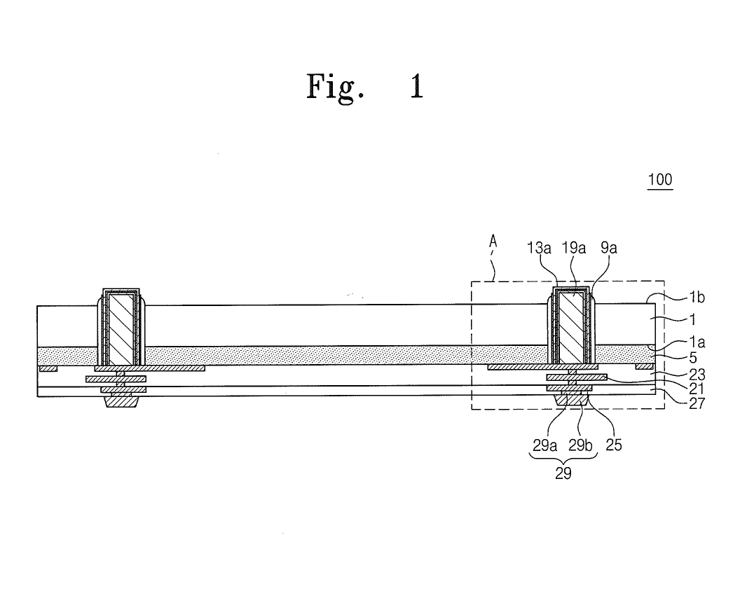

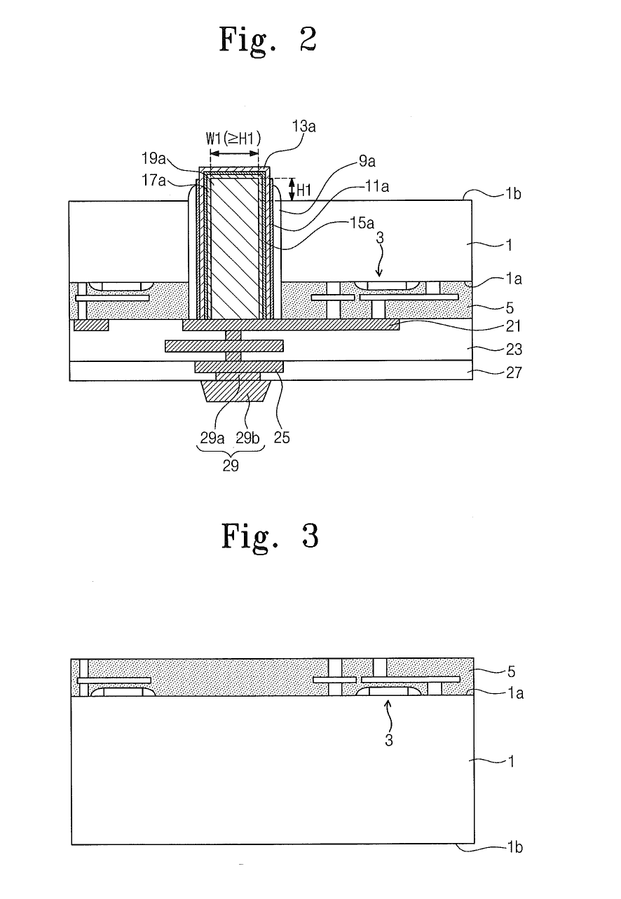

FIG. 1 is a cross sectional view exemplarily illustrating a semiconductor chip having a via middle structure according to example embodiments of the inventive concepts, and FIG. 2 is an enlarged cross sectional view of a portion A of FIG. 1.

Referring to FIGS. 1 and 2, a semiconductor chip 100 may include a substrate 1 and a through via 19a vertically penetrating the substrate 1 and serving as an electric pathway for transmitting electric signals. The substrate 1 may be a semiconductor substrate. The substrate 1 may include a first surface 1a (e.g., a front surface) and a second surface 1b (e.g., a back surface) facing each other. The first surface 1a may be an active surface, on which integrated circuit patterns are formed. For example, an integrated circuit 3 including a plurality of transistors may be provided on the first surface 1a. The integrated circuit 3 may include a memory circuit, a logic circuit or any combination thereof. The integrated circuit 3 may be covered with a first interlayer dielectric 5. The first interlayer dielectric 5 may be formed of at least one material selected from the group consisting of silicon oxide (e.g., SiO2), silicon nitride (e.g., SiN or Si3N4), and silicon oxynitride (e.g., SiON). The first interlayer dielectric 5 may be formed to have a single-layered or multi-layered structure. The first interlayer dielectric 5 may be covered with a second interlayer dielectric 23. Interconnection lines 21, which may be disposed at one or more level, may be formed in the second interlayer dielectric 23. The second interlayer dielectric 23 may be formed to have a single-layered or multi-layered structure. The through via 19a may penetrate the first interlayer dielectric 5 to be in contact with a portion of the interconnection lines 21. A diffusion barrier layer may be interposed between the through via 19a and the interconnection lines 21 to limit or even prevent copper elements from being diffused. The second interlayer dielectric 23 may be covered with a passivation layer 27. An uppermost interconnection line 25, which is electrically connected to the interconnection lines 21, may be provided between the second interlayer dielectric 23 and the passivation layer 27. The uppermost interconnection line 25 may be connected to a conductive bump 29 penetrating through the passivation layer 27. The conductive bump 29 may include a conductive pad 29a and a solder ball 29b. The solder ball 29b may be formed of an alloy of tin and silver (e.g., SnAg). The passivation layer 27 may be formed of a silicon nitride layer or an insulating polymeric material or the like.

Referring to FIGS. 1 and 2, the through via 19a may include a portion protruding outward from the second surface 1b of the substrate 1. In some embodiments, a width W1 of the through via 19a may be equivalent to or greater than a height H1 of the protruding portion of the through via 19a. For example, the through via 19a may be formed to have the height H1 of about 5 μm and the width W1 of about 7 μm to 8 μm. The through via 19a may be formed to include copper or tungsten. An insulating liner 9a may be interposed between the through via 19a and the substrate 1. The insulating liner 9a may be formed of a silicon oxide layer, which may be, for example, formed in a temperature condition of about 200° C. to 300° C. A wetting pattern (layer) 13a may be interposed between the insulating liner 9a and the through via 19a. The wetting pattern 13a may be formed of an oxidation-resistant material and include, for example, at least one material selected from the group consisting of gold (Au), palladium (Pd) and platinum (Pt). In some embodiments, the wetting pattern 13a may be formed using a physical vapor deposition method to have a thickness of about 0.2 μm or less. For example, the wetting pattern 13a may have a thickness ranging from about 0.01 μm to about 0.05 μm. In other embodiments, the wetting pattern 13a may be formed to have an atomic monolayer thickness or a thickness ranging from about 0.001 μm to about 0.005 μm.

A seed pattern (layer) 17a may be provided between the wetting pattern 13a and the through via 19a. The seed pattern 17a may be formed of a material including copper. A first barrier pattern (layer) 11a may be provided between the wetting pattern 13a and the insulating liner 9a, and a second barrier pattern (layer) 15a may be provided between the wetting pattern 13a and the seed pattern 17a. The first and second barrier patterns 11a and 15a may be formed of a material including at least one selected from the group consisting of titanium, titanium nitride, tantalum, and tantalum nitride. The second barrier pattern 15a may be configured to limit or even prevent copper elements, which may be included in the seed pattern 17a and the through via 19a, from being diffused. In addition, the first and second barrier patterns 11a and 15a may be configured to limit or even prevent gold elements, which may be included in the wetting pattern 13a, from being diffused. The first barrier pattern 11a may be interposed between the wetting pattern 13a and the insulating liner 9a to serve as an adhesive layer. The wetting pattern 13a, the second barrier pattern 15a and the seed pattern 17a may extend to cover a protruding surface of the through via 19a. In some embodiments, the first barrier pattern 11a and the insulating liner 9a may be formed to expose a sidewall of the wetting pattern 13a, while they protrude outward from the second surface 1b of the substrate 1.

In the semiconductor chip 100 described with reference to FIGS. 1 and 2, an end portion of the through via 19a, which protrudes outward from the second surface 1b of the substrate 1, may serve as a conductive pad or a conductive bump. Accordingly, there is no necessity to form an additional conductive pad or bump on the second surface 1b (or the back surface) of the substrate 1. This may simplify a structure of the semiconductor chip 100 and reduce a thickness of the semiconductor chip 100. Furthermore, this may be advantageous in that it may be possible to realize a semiconductor device or package having an increased density or capacity. As the protruding end portion of the through via 19a is covered with the wetting pattern 13a having the oxidation-resistant property, it may be possible to limit or even prevent a natural oxide layer from being formed between the solder ball and the wetting pattern 13a, when it will be subsequently jointed with the solder ball. This may improve a wetting property of the solder ball. In other words, the solder ball may be strongly attached to the wetting pattern 13a without the natural oxide layer, thereby reducing an electric resistance between the solder ball and the wetting pattern 13a. This may provide improved reliability of the semiconductor chip 100 or the semiconductor device or package. Furthermore, according to example embodiments of the inventive concepts, as both of the seed pattern 17a and the through via 19a, which may be formed of a copper-containing material, are encapsulated by the wetting pattern 13a and the second barrier pattern 15a, it is possible to effectively limit or even prevent copper elements from being diffused. As a result, it may be possible to limit or even prevent the semiconductor chip from being contaminated by the copper elements. This may improve further reliability of the semiconductor chip 100 or the semiconductor device or package.

FIGS. 3 through 9 are cross sectional views illustrating methods of fabricating the semiconductor chip of FIG. 2.

Referring first to FIG. 3, a substrate 1 with a first surface 1a and a second surface 1b may be provided. An integrated circuit 3 may be formed on the first surface 1a. A first interlayer dielectric 5 may be deposited on the first surface 1a to cover the integrated circuit 3.

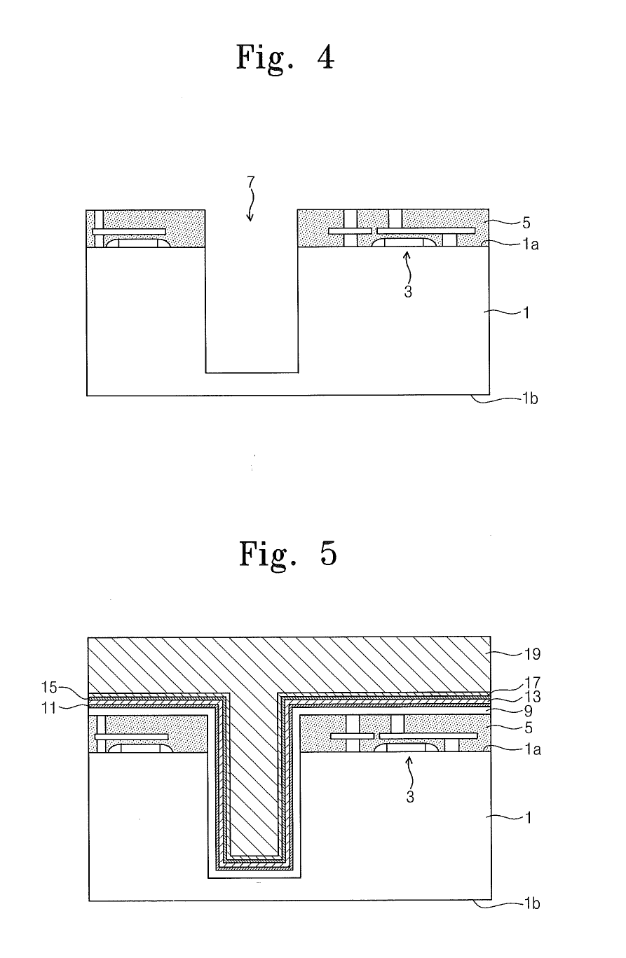

Referring to FIG. 4, the first interlayer dielectric 5 and the substrate 1 may be patterned to formed a through hole 7. Here, the through hole 7 may be formed to have a bottom surface spaced apart from the second surface 1b.

Referring to FIG. 5, an insulating liner layer 9, a first barrier layer 11, a wetting layer 13, a second barrier layer 15 and a seed layer 17 may be, sequentially and conformally, formed on the first surface 1a of the substrate 1 provided with the through hole 7. The insulating liner layer 9, the first barrier layer 11, the wetting layer 13, the second barrier layer 15 and the seed layer 17 may be formed using deposition processes. The insulating liner layer 9 may be a silicon oxide layer, which may be, for example, formed in a temperature condition of about 200° C. to 300° C. The wetting layer 13 may be formed of an oxidation-resistant material and include, for example, at least one material selected from the group consisting of gold (Au), palladium (Pd) and platinum (Pt). In some embodiments, the wetting layer 13 may be formed using a physical vapor deposition (PVD) or an atomic layer deposition (ALD) method. This may improve thickness uniformity and adhesiveness of the wetting layer 13, even in the case that the wetting layer 13 is very thin.

The first and second barrier layers 11 and 15 may be formed of a material including at least one selected from the group consisting of titanium, titanium nitride, tantalum, and tantalum nitride. For example, the seed layer 17 may be formed of copper. The deposition process may be performed using, for example, a chemical vapor deposition, a physical vapor deposition or an atomic layer deposition method. In some embodiments, a single fabricating line or apparatus may be used to perform the deposition processes of the insulating liner layer 9, the first barrier layer 11, the wetting layer 13, the second barrier layer 15 and the seed layer 17. This may reduce a cost and improve a manufacturing turn-around time. A conductive layer 19 may be formed on the seed layer 17 to fill the through hole 7 provided with the insulating liner layer 9, the first barrier layer 11, the wetting layer 13, the second barrier layer 15 and the seed layer 17. In some embodiments, the conductive layer 19 may be formed using an electroplating or electroless-plating process.

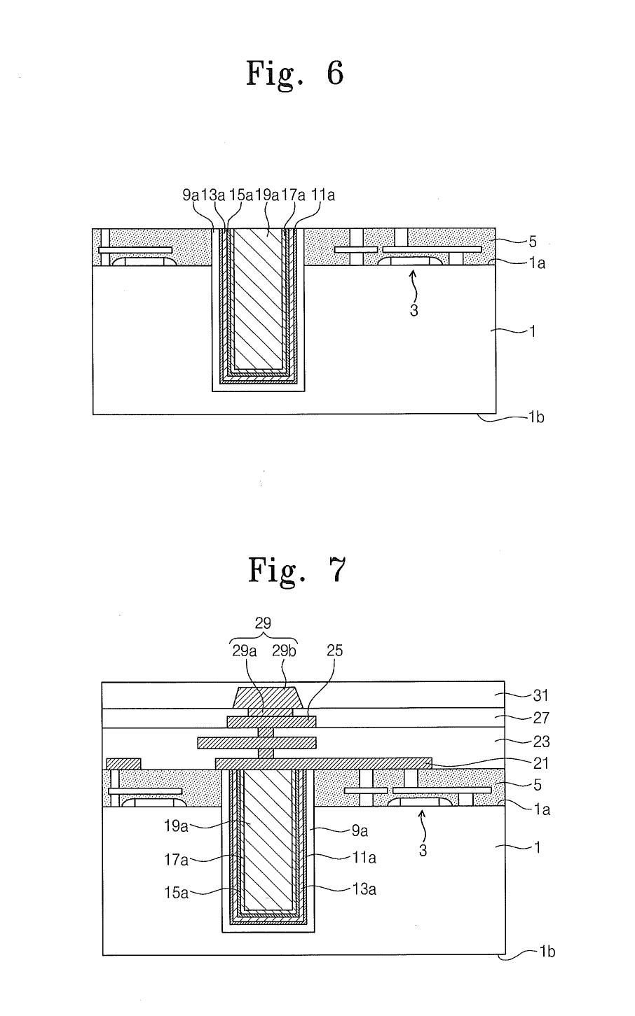

Referring to FIG. 6, a planarization process may be performed on the resultant structure of FIG. 5 to expose a top surface of the first interlayer dielectric 5, thereby forming an insulating liner 9a, a first barrier pattern 11a, a wetting pattern 13a, a second barrier pattern 15a, a seed pattern 17a and a through via 19a remaining in the through hole 7.

Referring to FIG. 7, interconnection lines 21 and a second interlayer dielectric 23 may be formed on the first interlayer dielectric 5. An uppermost interconnection line 25 may be formed on the second interlayer dielectric 23 to be electrically connected to the interconnection lines 21. Each of the first and second interlayer dielectrics 5 and 23 may be formed of silicon oxide layers. The interconnection lines 21 and 25 may be formed of a doped polysilicon or a metal-containing conductive material. A passivation layer 27 may be formed on the second interlayer dielectric 23 that exposes a portion of the uppermost interconnection line 25. The passivation layer 27 may be formed of silicon nitride or an insulating polymeric material. A conductive bump 29 may be formed on the passivation layer 27 that is in contact with the uppermost interconnection line 25. The conductive bump 29 may include a conductive pad 29a and a solder ball 29b and may be formed by successively performing two plating processes. The conductive pad 29a may be formed of a metallic material (e.g., of copper). The solder ball 29b may include at least one of alloys of tin and silver. After the formation of the conductive bump 29, a supporting structure 31 may be attached on the first surface 1a of the substrate 1 or on the passivation layer 27. The supporting structure 31 may be formed of a hard material (e.g., a glass substrate, a silicon substrate, a metal substrate, a polymer substrate) or a soft material (e.g., an elastic tape). In some embodiments, due to the presence of the supporting structure 31, the first surface 1a of the substrate 1 can be limited or even prevented from being damaged.

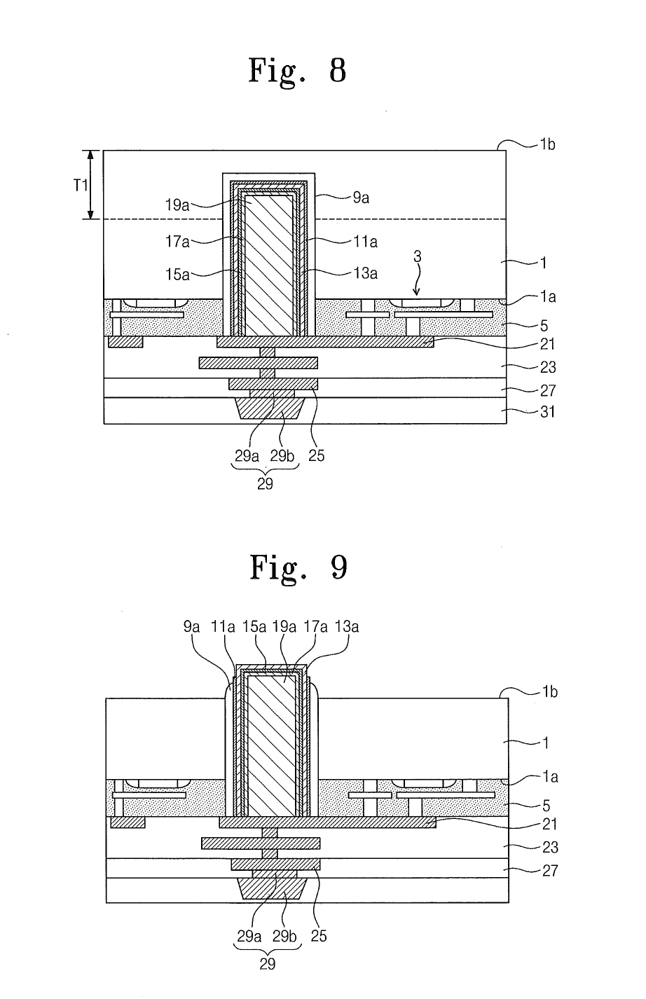

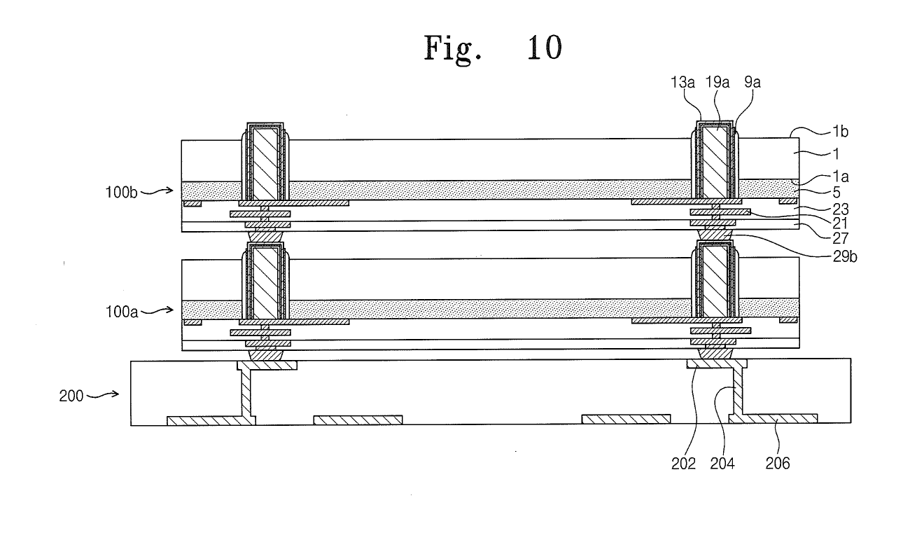

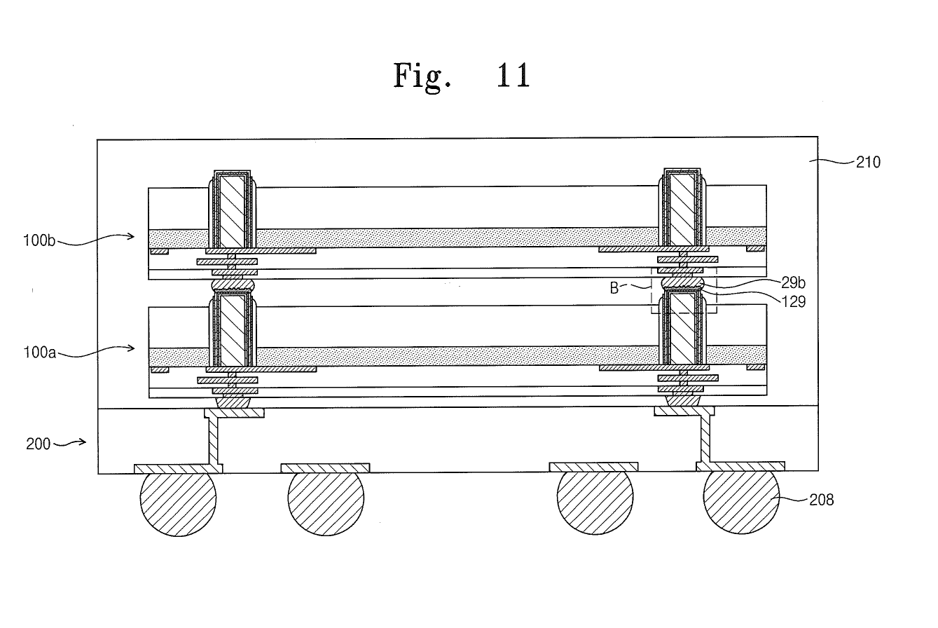

Referring to FIGS. 8 and 9, the substrate 1 provided with the supporting structure 31 may be inverted in such a way that the second surface 1b faces upward. Thereafter, an etch-back process may be performed on the entire second surface 1b of the substrate 1 to remove a back portion of the substrate 1 by a first thickness T1. In some embodiments, portions of the insulating liner 9a and the first barrier pattern 11a covering a bottom surface of the through via 19a may be removed to expose the wetting pattern 13a. A top surface of the insulating liner 9a may be located at a level equivalent to or lower than a top surface of the first barrier pattern 11a. Here, the through via 19a may protrude outward from the second surface 1b of the substrate 1.

Thereafter, the supporting structure 31 may be removed, as shown in FIG. 2.

Hereinafter, a process of packaging the semiconductor chip 100 will be described with reference to FIGS. 10 and 11.

FIGS. 10 and 11 are cross sectional views illustrating a method of fabricating a semiconductor package according to example embodiments of the inventive concepts, and FIG. 12 is an enlarged cross sectional view of a portion B of FIG. 11.

Referring to FIGS. 10 through 12, a first semiconductor chip 100a and a second semiconductor chip 100b may be stacked on a package substrate 200. The first and second chips 100a and 100b may be configured to have the same technical features as the semiconductor chip of FIG. 1. In some embodiments, the wetting pattern 13a of the first semiconductor chip 100a may be in contact with the solder ball 29b of the second semiconductor chip 100b. The package substrate 200 may include first pads 202, second pads 206, and vias 204 connecting the first and second pads 202 and 206. In some embodiments, the package substrate 200 may be a printed circuit board. A thermal process applying heat to the stacking structure may be performed, such that the solder ball 29b may be melted by the applied heat and be interfused with the wetting pattern 13a. As the result of the interfusion, an intermetallic compound (IMC) layer 129 (FIG. 12) may be formed between the solder ball 29b and the wetting pattern 13a. In some embodiments, there is no clear interface between the intermetallic compound layer 129 and the solder ball 29b. A portion of the intermetallic compound layer 129 may be formed in an upper portion of the wetting pattern 13a to cover partially a sidewall of the second barrier pattern 15a. The solder ball 29b may be formed to cover partially a sidewall of the wetting pattern 13a. Since the wetting pattern 13a is formed of an oxidation-resistant material, the solder ball 29b may be robustly attached to the wetting pattern 13a without a natural oxide layer interposed therebetween. In other words, the solder ball 29b can be strongly attached to the wetting pattern 13a, such that an interfacial resistance between the solder ball and the wetting pattern 13a can be reduced. This may improve reliability of the semiconductor package. Next, as seen in FIG. 1, outer solder balls 208 may be attached to the second pad 206 of the package substrate 200, and a molding layer 210 may be formed to encapsulate the semiconductor chips 100a and 100b.

In other embodiments, the second semiconductor chip 100b may be different from the semiconductor chip 100 of FIG. 1.

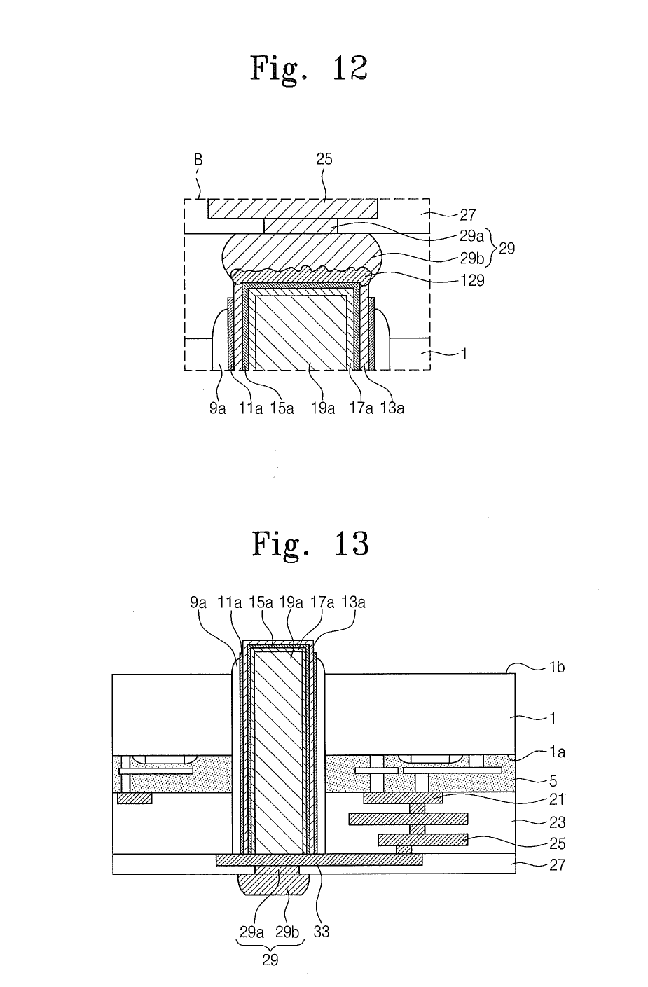

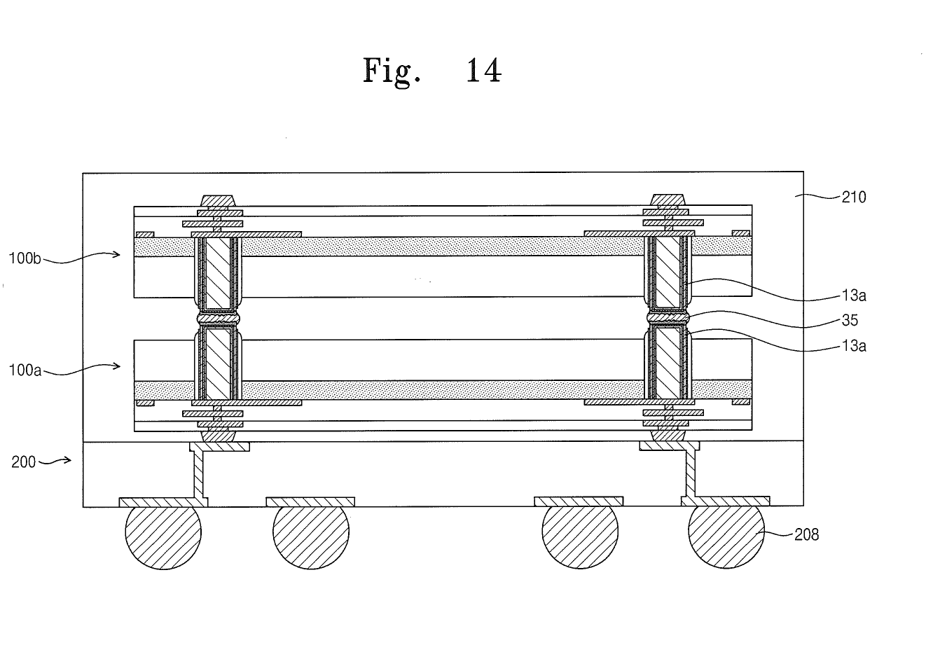

FIG. 13 is an enlarged sectional view of a semiconductor chip of a via last structure according to other example embodiments of the inventive concepts.

Referring to FIG. 13, a through via 19a may be formed to penetrate a substrate 1, a first interlayer dielectric 5, and a second interlayer dielectric 23 and be in contact with a redistributed line 33. The redistributed line 33 may be formed to electrically connect the through via 19a with an uppermost interconnection line 25. The semiconductor chip shown in FIG. 13 may be formed by forming the second interlayer dielectric 23 and the uppermost interconnection line 25, forming the through via 19a, and then forming the redistributed line 33. Except for this, the semiconductor chip of FIG. 13 may be formed using the substantially same fabricating method as that described with reference to FIG. 2 and have the substantially same configuration and/or structure as that of FIG. 2.

FIG. 14 is a sectional view of a semiconductor package according to other example embodiments of the inventive concepts.

Referring to FIG. 14, the first semiconductor chip 100a and the second semiconductor chip 100b may be stacked on the package substrate 200. According to these illustrated embodiments, the first and second chips 100a and 100b may be configured to have the same technical features as the semiconductor chip of FIG. 1, but the stacking of the second semiconductor chip 100b may be performed in an inverted posture. That is, the wetting pattern 13a of the first semiconductor chip 100a may be disposed to face the wetting pattern 13a of the second semiconductor chip 100b. Thereafter, an internal solder ball 35 may be disposed between the wetting patterns 13a of the first and second semiconductor chips 100a and 100b, and the resulting structure may be heated. As a result, the internal solder ball 35 may be melted and be attached to the wetting patterns 13a. The internal solder ball 35 may be a spherical solder ball or be formed using a self-assembly solder bonding process. In the self-assembly solder bonding process, a mixture containing solder particles and an adhesive resin may be coated between the wetting patterns 13a of the first and second semiconductor chips 100a and 100b and be heated up to a melting point of the solder particles or higher. In this case, the solder particles may be flowed in the adhesive resin, be moved to surfaces of the wetting patterns 13a, and then be attached to the surfaces of the wetting patterns 13a.

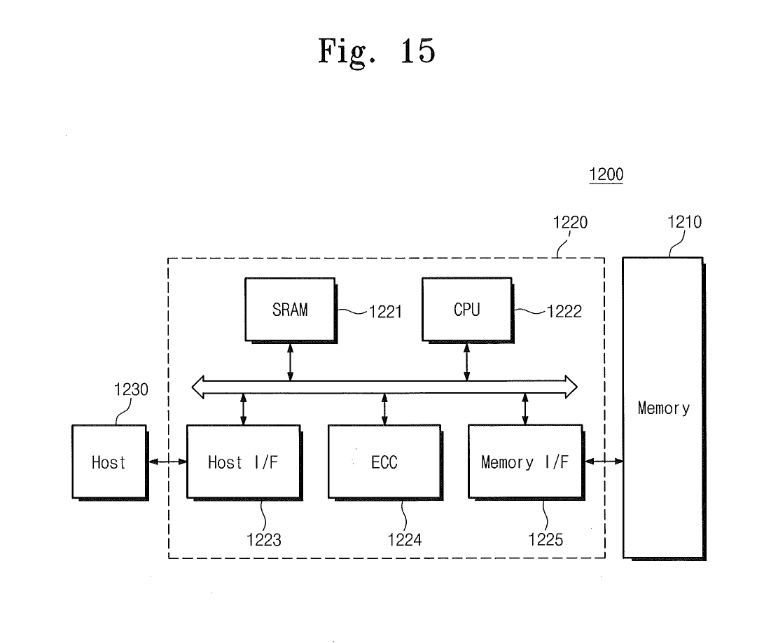

FIG. 15 is a block diagram of a memory card including a semiconductor device according to example embodiments of the inventive concepts.

Referring to FIG. 15, a memory card 1200 may include a memory controller 1220 controlling general data exchanges between a host and the memory device 1210. A static random access memory (SRAM) 1221 may be used as an operating memory of a processing unit (CPU) 1222. A host interface (I/F) 1223 may include a data exchange protocol of a host 1230 connected to a memory card 1200. An error correction block/circuit (ECC) 1224 may detect and correct errors included in data read from a multi-bit memory device 1210. A memory interface (I/F) 1225 may interface with the memory device 1210. The processing unit 1222 may perform general control operations for data exchange of the memory controller 1220. The memory card 1200 may be realized using a memory device 1210 including at least one of the semiconductor chips 100 and the semiconductor packages according to example embodiments of the inventive concepts.

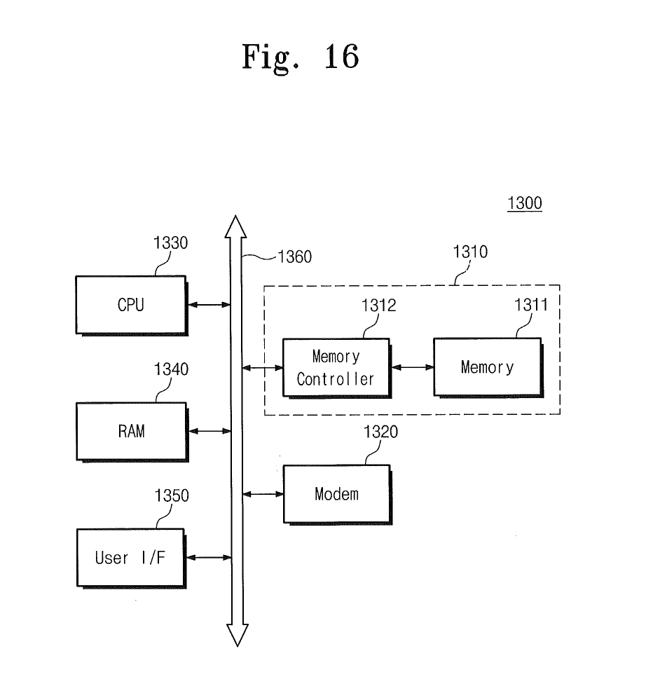

FIG. 16 is a block diagram of an information processing system including a semiconductor device according to example embodiments of the inventive concepts.

Referring to FIG. 16, an information processing system 1300 may be realized using a memory system 1310 including at least one of the semiconductor chips 100 and the semiconductor packages according to example embodiments of the inventive, concepts. For instance, the information processing system 1300 may be a mobile device and/or a desktop computer. In some embodiments, the information processing system 1300 may further include a modem 1320, a central processing unit (CPU) 1330, a random access memory (RAM) 1340, and a user interface (I/F) 1350, which are electrically connected to a system bus 1360, in addition to the memory system 1310. The memory system 1310 may include a memory device 1311 and a memory controller 1312. In some embodiments, the memory system 1310 may be configured substantially identical to the memory card 1200 described with respect to FIG. 15. Data processed by the CPU 1330 and/or input from the outside may be stored in the memory system 1310. In some embodiments, the memory system 1310 may be used as a portion of a solid state drive (SSD), and in this case, the information processing system 1300 may stably and reliably store a large amount of data in the memory system 1310. Although not illustrated, it is apparent to those skilled in the art that, for example, an application chipset, a camera image sensor, a camera image signal processor (ISP), an input/output device, or the like may further be included in the information processing system 1300 according to the inventive concepts.

According to example embodiments of the inventive concepts, the protruding through via of the semiconductor chip is covered with the wetting layer, and thus, there is no necessity to additionally form a conductive pad and a wetting layer. This may reduce a thickness of the semiconductor chip and simplify a structure of the semiconductor chip. As a result, it may be possible to realize a semiconductor device or package having an increased density or capacity.

In some embodiments, the solder ball is formed to be in contact with the wetting layer encapsulating the protruding through via. This may improve an adhesive strength between the solder ball and the wetting layer. In addition, the solder ball and the wetting layer may be attached to each other without a natural oxide layer interposed therebetween, and this may improve reliability of the semiconductor package.

In some embodiments, a method of fabricating a semiconductor chip may include forming the insulating liner using a chemical vapor deposition method and forming the first barrier layer, the wetting layer, the second barrier layer, and the seed layer using physical vapor deposition method. This may reduce a cost and improve a manufacturing turn-around time.

As described above, embodiments of the inventive concepts may provide a highly reliable and high density semiconductor chip and a semiconductor package including the same.

Other embodiments of the inventive concepts may provide a fabricating method of a semiconductor chip capable of reducing a cost and improve a manufacturing turn-around time.

According to example embodiments of the inventive concepts, a semiconductor chip may include a substrate, a through via penetrating the substrate, a wetting layer interposed between the through via and the substrate, and a seed layer interposed between the wetting layer and the through via.

In some embodiments, the through via may include a portion protruding outward from a surface of the substrate. Here, a width of the through via may be equivalent to or greater than a height of the protruding portion of the through via.

In some embodiments, the chip may further include a first barrier layer interposed between the wetting layer and the substrate and a second barrier layer interposed between the wetting layer and the seed layer.

In some embodiments, the wetting layer, the second barrier layer and the seed layer may extend to cover a top surface of the through via, and the first barrier layer may be formed to partially expose a sidewall of the wetting layer.

In some embodiments, the seed layer and the through via may be formed of copper containing materials, and the wetting layer may be formed of a material including at least one selected from the group consisting of gold (Au), palladium (Pd) and platinum (Pt).

According to example embodiments of the inventive concepts, a semiconductor package may include a package substrate, a plurality of semiconductor chips stacked on the package substrate, and solder balls interposed between the semiconductor chips to electrically connect the semiconductor chips with each other. At least one of the semiconductor chips may include a first substrate, a first through via penetrating through and protruding from the first substrate, a first wetting layer interposed between the first substrate and the first through via, and a first seed layer interposed between the first wetting layer and the first through via. In addition, the solder ball and the first wetting layer may be connected to each other with an intermetallic compound layer interposed therebetween.

In some embodiments, at least one of the remaining ones of the semiconductor chips may include a conductive pad, and the solder ball may be in contact with both of the intermetallic compound layer and the conductive pad.

In some embodiments, the intermetallic compound, layer may extend to cover at least a portion of a sidewall of the first seed layer.

In some embodiments, at least one of the remaining ones of the semiconductor chips may include a second substrate, a second through via penetrating the second substrate, a second wetting layer interposed between the second substrate and the second through via, and a second seed layer interposed between the second wetting layer and the through via. The solder ball may be in contact with both of the first wetting layer and the second wetting layer.

In some embodiments, a method of fabricating a semiconductor chip may include forming a hole in a substrate, conformally forming a wetting layer in the hole, conformally forming a seed layer on the wetting layer, forming a through via on the seed layer to fill the hole, and then, removing a lower portion of the substrate to expose the wetting layer.

In some embodiments, the wetting layer and the seed layer may be formed using deposition processes, and the through via may be formed using a plating process.

The foregoing is illustrative of the present inventive concept and is not to be construed as limiting thereof. Although a few embodiments of the present inventive concept have been described, those skilled in the art will readily appreciate that many modifications are possible in the embodiments without materially departing from the novel teachings and advantages of the present inventive concept. Accordingly, all such modifications are intended to be included within the scope of the present inventive concept as defined in the claims. Therefore, it is to be understood that the foregoing is illustrative of the present inventive concept and is not to be construed as limited to the specific embodiments disclosed, and that modifications to the disclosed embodiments, as well as other embodiments, are intended to be included within the scope of the appended claims. The present inventive concept is defined by the following claims, with equivalents of the claims to be included therein.

1. A semiconductor device, comprising:
a substrate;
a through via penetrating the substrate and having a protruding portion at a first end thereof extending out from a first surface of the substrate and a second end of the via contacting an interconnection line proximate a second, opposite, end of the substrate; and
a wetting layer positioned between the via and the substrate and extending over the protruding portion of the via, wherein the wetting layer includes a material selected to improve an adhesive strength between the wetting layer and a solder ball contacting the wetting layer extending over the protruding portion of the via when a solder ball is coupled to the wetting layer.

2. The semiconductor device of claim 1, wherein the wetting layer includes at least one of gold (Au), palladium (Pd) and platinum (Pt) and wherein the device further comprises:
a first barrier layer interposed between the wetting layer and the substrate, wherein the first barrier layer does not extend over at least a portion of the protruding portion; and
a second barrier layer interposed between the wetting layer and the via, wherein the first and second material layer comprise a material selected to limit diffusion of gold (Au), palladium (Pd) and platinum (Pt) from the wetting layer.

3. The semiconductor device of claim 2, wherein the first barrier layer extends over only a lower portion of sidewalls of the protruding portion and does not extend over an upper portion of the sidewalls or an upper surface of the protruding portion so that the solder ball contacting the wetting layer on the upper surface and the upper portion of the sidewalls of the protruding portion.

4. The semiconductor device of claim 3, further comprising a seed layer positioned between the via and the second barrier layer, wherein at least one of the seed layer and the via include copper and wherein the second barrier layer comprises a material selected to limit diffusion of copper from the at least one of the seed layer and the via.

5. The semiconductor device of claim 4, wherein the first barrier layer and the second barrier layer include at least one of titanium, titanium nitride, tantalum, and tantalum nitride and wherein the device further comprises a contact barrier layer positioned between the at least one of the seed layer and the via and the interconnection line, wherein the contact barrier layer comprises a material selected to limit diffusion of copper from the at least one of the seed layer and the via to the interconnection line.

6. A semiconductor package including the semiconductor device of claim 1 as a first semiconductor device, the semiconductor package further comprising:
a second semiconductor device stacked on the first semiconductor device and having a conductive component positioned proximate the protruding portion of the via; and
the solder ball positioned between the wetting layer and the conductive component of the second semiconductor device and forming an electrical connection between the via and the conductive component including an intermetallic component (IMC) layer formed by interfusion between the wetting layer and the solder ball.

7. The semiconductor package of claim 6, wherein the IMC layer extends to cover at least a portion of a sidewall of the protruding portion of the via having the wetting layer thereon.

8. The semiconductor package of claim 6, wherein the second semiconductor device includes a through via penetrating a substrate thereof and having a protruding portion and wherein the protruding portion of the through via of the second semiconductor device is positioned proximate the protruding portion of the via of the first semiconductor device with the solder ball and IMC therebetween.

9. The semiconductor package of claim 6, wherein the second semiconductor device includes a through via penetrating a substrate thereof and having a protruding portion at a first end thereof and an interconnection line proximate a second, opposite end thereof and wherein the solder ball is positioned between the protruding portion of the first semiconductor device and the interconnection line of the second semiconductor device.

10-11. (canceled)

12. A semiconductor chip, comprising:
a substrate;
a through via penetrating the substrate;
a wetting layer interposed between the through via and the substrate; and
a seed layer interposed between the wetting layer and the through via.

13. The chip of claim 12, wherein the through via comprises a portion protruding outward from a surface of the substrate.

14. The chip of claim 13, wherein a width of the through via is equivalent to or greater than a height of the protruding portion of the through via.

15. The chip of claim 13, further comprising,
a first barrier layer interposed between the wetting layer and the substrate; and
a second barrier layer interposed between the wetting layer and the seed layer.

16. The chip of claim 15, wherein the wetting layer, the second barrier layer and the seed layer extend to cover a top surface of the through via, and
the first barrier layer is formed to partially expose a sidewall of the wetting layer.

17. The chip of claim 12, wherein the seed layer and the through via comprises copper, and
the wetting layer is formed of a material including at least one selected from the group consisting of gold (Au), palladium (Pd) and platinum (Pt).

18-24. (canceled)
